(19) United States
(12) Patent Application Publication
(10) Pub. No.: US 2008/0246006 A1
(43) Pub. Date: Oct. 9, 2008

(54) Cdte/Gsh Core-Shell Quantum Dots

(75) Inventors: Jackie Y. Ying, Singapore (SG); Yuangang Zheng, Singapore (SG); Shujun Gao, Singapore (SG)

Correspondence Address: DINSMORE & SHOHL LLP, ONE DAYTON CENTRE, ONE SOUTH MAIN STREET, SUITE 1300, DAYTON, OH, 45402-2023, US

(73) Assignee: AGENCY FOR SCIENCE, TECHNOLOGY AND RESEARCH, (SG)

(21) Appl. No.: 11/910,305

(22) PCT Filed: Jan. 11, 2006
(86) PCT No.: PCT/SG06/00003

§ 371 Date: Jan. 28, 2008

Related U.S. Application Data
(60) Provisional application No. 60/666,731, filed on Mar. 31, 2005.

(51) Int. Cl. H01L 51/50; C09K 11/02

(52) U.S. Cl. 252/301.36; 438/99; 977/774; 257/E51.001

(57) ABSTRACT

Quantum dots, each having a core comprising CdTe and a shell comprising GSH covering the core, are provided. The Quantum dots can be formed in a solution comprising a telluride (Te) precursor and a cadmium (Cd) precursor for forming the cores, and glutathione (GSH) for forming shells covering the cores. The cores can comprise CdTe nanocrystals grown in the solution. The growth of the nanocrystals can be limited. The quantum dots can have high fluorescence emission quantum yield such as up to about 45%, and small sizes such as from about 3.8 nm to about 6 nm.

### CROSS-REFERENCE TO RELATED APPLICATIONS

This application claims the benefit of U.S. provisional application Ser. No. 60/666,731 filed Mar. 31, 2005, the contents of which are incorporated herein by reference.

### FIELD OF THE INVENTION

The present invention relates to quantum dots.

### BACKGROUND OF THE INVENTION

Quantum dots (QDs) have wide applications and are currently commercially available. For example, QDs may be useful in optoelectronic and photovoltaic devices, optical amplifier media for telecommunication networks, and for bio-labeling.

Typically, a QD is a nanocrystal particle having a semiconductor core and a semiconductor shell outside the core. The size of the QDs is typically from 2 to 20 nm. Due to their small sizes, QDs have a well-defined fluorescence emission spectrum. Conventionally, QDs can have a thiol shell and are often coated with a suitable material, such as polymers and silica. The shell and the polymer coating are typically used to improve or alter the properties of the QDs, such as the optical properties, stability, and affinity to another object of the QDs. For instance, the shell and coating may improve the fluorescence quantum yield of the QDs. Quantum yield is the number of photons emitted per absorbed photon and is often a critical property, such as when the QDs are used as labels.

However, the conventional QDs have some drawbacks. Polymer-coated QDs are larger in size and thus have limited applications. While QDs with only a thiol shell are smaller in size, they are typically inferior in terms of fluorescence quantum yield and long-term stability as compared to polymer-coated QDs.

For example, Thiol-capped CdTe QDs can be formed by an aqueous synthesis technique as disclosed in Nikolai Gaponik et al. (“Gaponik”), “Thio-capping of CdTe Nanocrystals: An Alternative to Organometallic Synthetic Routes,” Journal of Physical Chemistry B, vol. 106, pp. 7177-7185, 2002, the contents of which are incorporated herein by reference. However, a problem with these thiol-capped QDs is that they have low quantum yield typically in the range of 1 to 10%. Although the quantum yield can be improved by various post-formation treatments such as photochemical etching, size selective precipitation and long-term illumination, the purified or activated QDs have a tendency to agglomerate during these treatments, thus forming larger sized particles.

CdSe QDs have been synthesized in water using glutathione as a stabilizing molecule, as reported in Monika Bäumle et al. (“Bätumle”), “Highly Fluorescent Streptavidin-Coated CdSe nanoparticles: Preparation in Water, Characterization, and Micropatterning,” Langmuir, vol. 20, pp. 3838-3831, 2004, the contents of which are incorporated herein by reference. However, a problem with the technique disclosed in Bäumle is that the CdSe QDs have a relatively low quantum yield of 16%. Another problem with this technique is that the QDs prepared are tunable only in a narrow range of wavelengths, because the QDs formed tend to aggregate when they grow to sizes larger than about 3 nm.

Accordingly, there is a need for QDs that are of relatively small sizes and high quantum yield. There is also a need for a method and a solution for preparing QDs having these properties, and QDs that are tunable over a wide range of wavelengths.

### SUMMARY OF THE INVENTION

According to an aspect of the present invention, there is provided a method of synthesizing quantum dots. In this method, a solution comprising a telluride (Te) precursor and a cadmium (Cd) precursor is provided. Nanocrystals comprising CdTe are grown in the solution. Glutathione (GSH) is also introduced to the solution to form shells covering the nanocrystals. The nanocrystals and the shells form quantum dots each having a core comprising CdTe and a shell comprising GSH.

According to another aspect of the present invention, there is provided a quantum dot comprising a nanocrystal core and a shell covering the core. The core comprises cadmium telluride (CdTe). The shell comprises glutathione (GSH).

According to a further aspect of the present invention, there is provided a solution for forming quantum dots each comprising a CdTe core and a GSH shell. The solution comprises a telluride (Te) precursor and a cadmium (Cd) precursor for forming CdTe cores, and glutathione (GSH) for forming shells covering the CdTe cores.

According to yet another aspect of the present invention, there is provided a method of synthesizing quantum dots. In this method, quantum dots are formed in a solution comprising a telluride (Te) precursor, a cadmium (Cd) precursor, and glutathione (GSH), such that each of the quantum dots has a core comprising CdTe and a shell comprising GSH.

Advantageously, the quantum dots can have fluorescence quantum yields higher than about 16%, such as up to about 45%. The quantum dots can also have diameters ranging from about 3.8 nm to about 6 nm.

Other aspects and features of the present invention will become apparent to those of ordinary skill in the art upon review of the following description of specific embodiments of the invention in conjunction with the accompanying figures.

### BRIEF DESCRIPTION OF THE DRAWINGS

In the figures, which illustrate, by way of example only, embodiments of the present invention,

FIG. 1 is a schematic diagram of a quantum dot;

FIG. 2 is a line graph of absorption and fluorescence spectra;

FIG. 3 is a graph of fluorescence emission peak wavelength as a function of heating time;

FIG. 4 is a graph of quantum yield and bandwidth as a function of wavelength;

FIG. 5 is a graph of size distribution measured by Dynamic Light Scattering (DLS);

FIG. 6 is a transmission electron microscopy (TEM) image of sample quantum dots;

FIG. 7 is a line graph of X-ray Diffraction (XRD) patterns of two types of quantum dots;

FIG. 8 is a line graph of fluorescence intensity as a function of pH;

FIG. 9A is a confocal fluorescence image of cells labeled with quantum dots; and

FIG. 9B is a transmission image of cells labeled with quantum dots.

### DETAILED DESCRIPTION

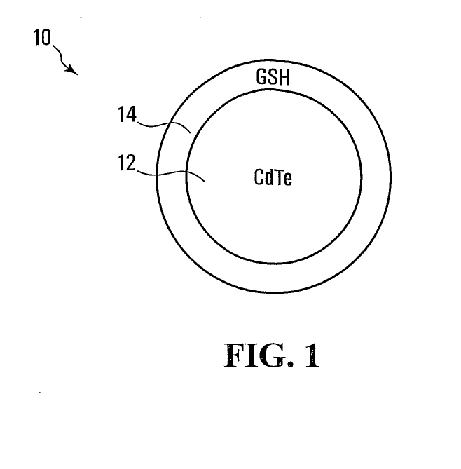

FIG. 1 illustrates a quantum dot (QD) 10, exemplary of embodiments of the present invention. Quantum dots are also referred to by various other names such as nanocrystals, nanoparticles, and quantum bits.

Quantum dot 10 comprises a core 12 and a shell 14. Core 12 includes a semiconductor nanocrystal, such as cadmium telluride (CdTe), which can have a zinc blende lattice structure. Core 12 has a diameter from about 2.8 nm to about 5 nm. Shell 14 includes a stabilizing agent glutathione (GSH) and has a thickness of about 0.5 nm. The external diameter of QD 10 is therefore about 3.8 to about 6 nm.

As can be understood by persons skilled in the art, the sizes of QDs can be measured using various techniques, including conventional techniques such as X-ray diffraction (XRD). The sizes of QDs can also be estimated based on the known relationship between fluorescence emission peak wavelength and nanocrstal size. While the XRD approach may be more accurate, the emission peak approach can also be reliable and can be more convenient. Example techniques have been described in X. Michalet et. al., “Quantum Dots for Live Cells, in Vivo Imaging, and Diagnostics,” Science, vol. 307, pp. 538-541, 2005, the contents of which are incorporated herein by reference.

The molar ratio of Cd:Te in the core can vary from about 2.5:1 to about 3.5:1. This ratio may vary with core size. For example, when the core has a diameter of about 4 nm, the ratio is about 3.3:1.

Quantum dot 10 has a fluorescence quantum yield higher than about 16%, such as up to about 45%. The quantum yield of QD 10 may be from about 20% to about 25% with an emission peak wavelength in the range of about 520 to about 620 nm, such as when it is formed with NaHTe as the Te precursor. The quantum yield of QD 10 may also be from about 30% to about 45% with an emission peak wavelength in the range of from about 500, or about 520 nm, to about 620 nm, such as when it is formed with H₂Te as the Te precursor. As aforementioned, quantum yield is the number of photons emitted per absorbed photon. Quantum yield may be measured using any suitable technique. Suitable techniques are known to persons skilled in the art. For example, fluorescein is conventionally used as the reference standard. The peak bandwidth is from about 30 nm to about 52 nm. As can be appreciated, the peak bandwidth refers to the Full Width at Half Maximum (FWHM) around the peak.

According to a process exemplary of embodiments of the present invention, quantum dots 10 can be formed from a solution, which includes a telluride (Te) precursor, a cadmium (Cd) precursor, and glutathione (GSH). In this exemplary process, the Te and Cd precursors are provided in the solution for forming CdTe nanocrystals, and the GSH is introduced to the solution for forming shells covering the nanocrystals. The solution may be aqueous, i.e., having water as a solvent. The solution may be heated to accelerate the growth of the nanocrystals, as will be further discussed below.

The molar ratio of Cd, Te, and GSH in the solution can vary. For example, the molar ratio of Cd:Te may vary from about 3:1 to about 7:1, and the molar ratio of Te:GSH may vary from about 1:2 to about 1:10. The molar ratios can affect the properties of the resulting QDs and the time required to form the QDs. It can be advantageous if the molar ratio is about 5:1:5 (Cd:Te:GSH), as the resulting QDs can have relatively high quantum yield. The Te precursor and Cd precursor can be any suitable chemical compounds for reacting with each other to form cores 12. For example, the Te precursor can include sodium hydrotelluride (NaHTe) or hydrogen telluride (H₂Te), or a combination of both. It can be advantageous to use H₂Te as the Te precursor as the resulting QDs can have a better quality, such as higher quantum yield, than QDs synthesized with NaHTe as the Te precursor. The Cd precursor can include a water-soluble Cd salt such as cadmium chloride (CdCl₂), cadmium perchloride, cadmium acetate, and the like, or any combination thereof. The solution has a pH value above about 11.0. It can be advantageous to have a pH value from about 11.2 to about 11.8, such as about 11.5.

The solution may be prepared by mixing two precursor solutions each respectively containing one or the other of the two precursors. For example, the solution may be prepared by mixing a Cd precursor solution and a Te precursor solution. One of the precursor solutions may also contain GSH, so as to introduce GSH to the resulting solution. The precursor solutions may be mixed by “one-shot” mixing. Other mixing techniques, such as drop-wise mixing, may also be used. However, it may be advantageous to apply the “one-shot” mixing technique as it can result in improved results such as higher quantum yields and narrower bandwidths. It has been found that “one-shot” mixing can result in narrower initial particle size distribution than drop-wise mixing. As can be appreciated, narrow size distribution of the nanocrystals can be advantageous.

As can be understood by persons skilled in the art, mixing of the precursors can also be carried out by bubbling a gas comprising a precursor, such as H₂Te as the Te precursor, through a solution comprising another precursor, such as a Cd precursor. It may be advantageous to prepare the mixture of the precursors in this manner, as will become apparent below.

As will be understood, CdTe nanocrystals can form and grow by self-assembly in the solution upon mixing of the precursors at an appropriate temperature. A glutathione shell can form immediately after a CdTe nanocrystal core is formed, by binding to the surface of newly-formed nanocrystal. Typically, the shell comprises a monolayer of glutathione, which has a thickness of about 0.5 nm. After the shell is formed, the core can further grow because Cd and Te ions can penetrate or permeate through the shell. Thus, the nanocrystals will continue to grow under suitable conditions, which can be understood by persons skilled in the art. For example, within a limit, at higher temperatures the nanocrystals will grow faster. Thus, by adjusting growth temperature and growth time, the sizes of the QDs formed can be controlled, or, in other words, the fluorescence emission peak can be tuned.

The solution can be heated at a suitable temperature for a selected period of time. For example, an aqueous solution containing a mixture of the Cd precursor solution and Te precursor solution can be heated to about 95° C. for up to about 90 minutes to form QDs. The heating temperature can vary and can be readily determined in a particular application by persons skilled in the art. For example, the heating temperature will be limited by the boiling temperature of the solution. For an aqueous solution, the heating temperature should be below about 100° C. at normal conditions.

When the growth temperature is maintained at a sufficiently high temperature, such as about 95° C., nanoparticles can continue to grow at a relatively high rate. When the temperature of the solution is reduced, such as to below room temperature, the growth rate can drop significantly. Thus, the heating time can be selected to control the resulting sizes of the formed quantum dots. In some embodiments, a heating time of less than about 90 minutes may be appropriate. The particular heating time in any particular application can be assessed depending on various factors such as the heating temperature, the contents of the solution, the desired sizes of the final QDs, and the like. The heating time may be selected to limit growth of the nanocrystals such that the resulting quantum dots have core diameters (diameters of the cores) from about 2.8 nm to about 5 nm. The heating time may also be selected so that the core diameters have an average diameter of about 4 nm. The external diameters of the formed quantum dots may vary from about 4 to about 6 nm, depending on the heating time. As can be appreciated, the heating time can also be selected to limit growth of the nanocrystals so that a formed quantum dot has a selected fluorescence emission spectrum, which is dependent on the size of the quantum dot. As the heating time and thus the sizes of formed quantum dots vary, their fluorescence spectra may peak at different wavelengths ranging from about 500 to about 620 nm, as will be illustrated in the following example.

After heating for the selected period of time, the solution can be rapidly cooled to prevent significant further growth of the nanoparticles, thus forming quantum dots 10 with desired sizes, or with sizes in a selected range. Cooling can be carried out in any suitable manner. For example, the solution can be cooled by being immersed in an ice bath. Rapid cooling can be advantageous for obtaining QDs with desired fluorescence emission characteristics. For instance, the sizes of the formed QDs can vary only within a narrow range when the solution is cooled rapidly. However, when it is not necessary to have a narrow size distribution, the solution may be cooled slowly.

Additional information on synthesizing QDs can be found in the literature, such as in Bätumle and Gaponik.

### EXAMPLES

Sample QDs were prepared with the following example procedure, where all reactions were carried out in oxygen-free water under an argon gas environment.

Step 1. A Te precursor was prepared, according to one of two protocols. According to Protocol One, a precursor solution containing sodium hydrotelluride (NaHTe) was prepared by reacting sodium borohydride (NaBH₄) with tellurium powder (Te) in water. The Te powders were of 99.8% stated purity and 200 mesh. The NaBH₄ was slightly excessive. According to Protocol Two, an H₂Te gas was prepared by reacting aluminum telluride (Al₂Te₃) with 0.5 M sulphuric acid (H₂SO₄).

Step 2. A precursor solution containing CdCl₂ and glutathione (GSH) with a pH of about 11.5 was prepared.

Step 3. A mixture solution was prepared. According to Protocol One, the two precursor solutions from Steps 1 and 2 were mixed by “one-shot” mixing. According to Protocol Two, the H₂Te gas from Step 1 was bubbled through the precursor solution from Step 2, for a few minutes. In either case, the mixture solution was vigorously stirred. The mixture solution had a total volume of 300 ml. The respective molar contents of Cd, Te, and GSH in the mixture solution were 3, 0.6, and 3 mmol.

Step 4. The mixture solution was heated at a temperature of about 95° C. for various time periods. It took about two minutes to heat the solution from room temperature to 95° C. GSH-capped CdTe QDs grow quickly upon reaching the temperature of about 95° C.

Step 5. After the selected heating time, the heated solution was immersed in an ice bath to stop further growth of QDs. For different samples, heating was stopped after different lengths of time to obtain QDs of different particle sizes and fluorescence emission spectra.

Step 6. The prepared QDs were precipitated and washed several times in 2-propanol, forming pellets of QDs. Excess salt, such as NaCl, NaOH and excess GSH, was removed by washing.

Step 7. The pellets were dried at room temperature in vacuum overnight, forming powders of sample QDs.

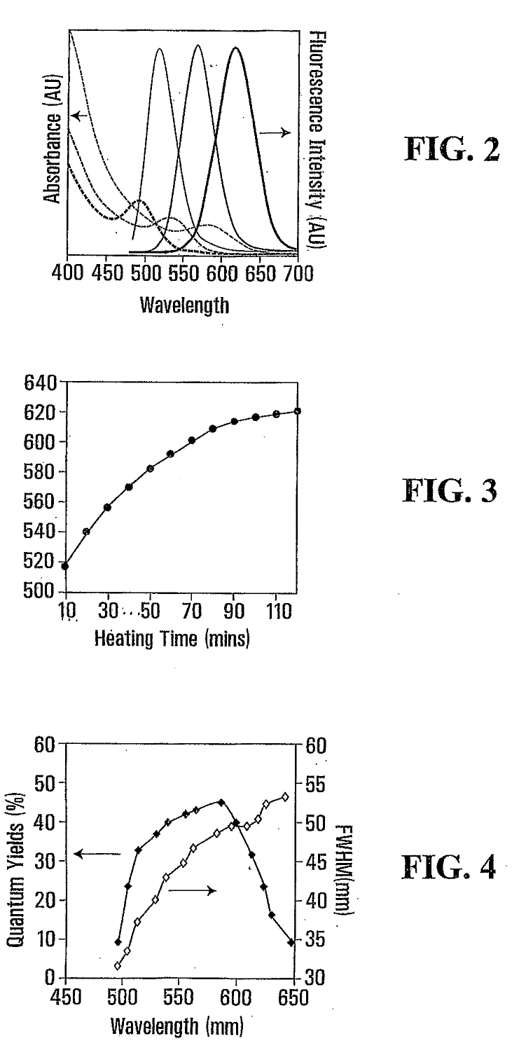

Absorption and fluorescence spectra of the sample QDs were measured at room temperature using an Agilent™ 843 UV-Vis spectrometer and a Jobin Yvon Horiba Fluorolog™ fluorescence spectrometer, respectively. The fluorescence spectra were obtained by scanning from 480 nm to 700 nm with 470 nm excitation. The fluorescent color detected from the sample QDs changed from green (after about 10 minutes of heating) to red (after about 90 minutes of heating). Exemplary measurement results of the absorption and fluorescence emission spectra are shown in FIG. 2. The dashed lines represent the absorption spectra and the solid lines represent the fluorescence spectra. The spectra shown are for sample QDs formed after 10, 40 and 90 minutes of heating, respectively. At about 400 nm, the absorbance increases as heating time increases. The emission peak shifts to higher wavelength when heating time increases.

FIG. 3 shows measured dependence of emission peak wavelength on heating time. As can be seen, the peak wavelength increases from about 520 nm to about 620 nm as heating time increases from about 10 minutes to about 120 minutes. As can also be seen, the peak shifts little after about 90 minutes of heating.

The quantum yields and bandwidths of sample QDs were also measured. Some results are shown in FIG. 4. The quantum yield was determined by measuring the integrated fluorescence intensities of the sample QDs and a reference solution which was a fluorescein solution in basic ethanol and had a quantum yield of 0.97. For these measurements, the QD samples were diluted to yield absorption of 0.1 at 470 nm. As can be seen, the quantum yields varied from about 10% to about 45%, and the bandwidth varied from about 30 nm to about 52 nm. The maximum quantum yield measured is about 45% at about 600 nm. The quantum yield is above 16% over a broad spectral range, from about 500 to about 625 nm. The quantum yield is between about 30% to about 45% over the range of about 510 nm to about 620 nm. These values are much higher than CdTe QDs capped by other thiol ligands, which typically exhibit quantum yields in the range of 1 to 10%.

Without being limited to a particular theory, it is possible that the glutathione shell stabilizes the geometry of the CdTe nanocrystal core, thus leading to increased quantum yield. As is known, QDs may have surface defects which can dramatically affect their quantum yield. The geometry of surface atoms will change as the nanocrystals change their size. At certain core size, the surface geometry may be optimal for, for example, the GSH-Cd interaction. However, if the core size is too large or too small, there can be geometry mismatch between the stabilizing agent and the surface core atom such as Cd atoms. The mismatch can result in an unsmooth, defected surface, thus a reduced quantum yield.

Experimental results also show that QDs prepared according to Protocol One exhibit lower quantum yields than those of QDs prepared according to Protocol Two. Without being limited to a particular theory, it is possible that more Teₙ²⁻ clusters are formed in the mixture solution in Protocol One than in Protocol Two, and the presence of Teₙ²⁻ clusters increases defects in the initially formed CdTe nanocrystals. Thus, CdTe nanocrystals formed according to Protocol Two may contain fewer defects than those formed according to Protocol One.

The size distribution of the sample QDs were measured with Dynamic light scattering (DLS) technique in an aqueous solution. The sample QD powder was dissolved in deionized water with a final concentration up to 300 mg/ml. The measurements were performed on a BI-200SM™ laser light scattering system, provided by Brookhaven Instruments Corporation™. The measured external diameters of the sample QDs vary from about 3.8 nm to about 6 nm.

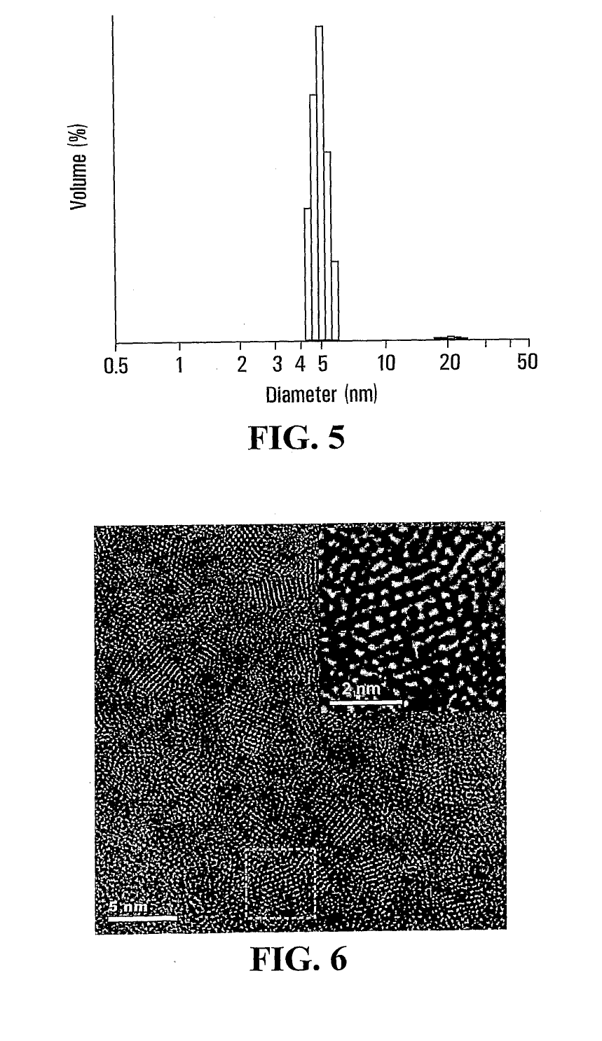

The data shown in FIGS. 5 to 8, 9A and 9B were collected from QDs formed with about 90 minutes of heating. These QDs had a fluorescence emission peak at about 600 nm.

FIG. 5 shows the measured results for sample QDs having a fluorescence emission peak at 600 nm and quantum yield of 26%. As shown, the external diameters of the QDs vary from about 4.3 nm to about 6 nm and the average external diameter is about 5 nm. With a shell thickness of about 0.5 nm, the core diameters are from about 2.8 nm to about 5 nm, and the average core diameter is about 4 nm. Only about 1 v % (volume percent) of the QDs was aggregated to form clusters of the size of 10 to 20 nm.

Transmission electron microscopy (TEM) images of the sample QDs were obtained with an FEI Tecnai TF-20™ field emission high-resolution TEM (200 kV). An example TEM image is shown in FIG. 6, which illustrates the crystallinity of the sample QDs. The inset at the top-right corner is a magnified image of the portion enclosed by the dotted line.

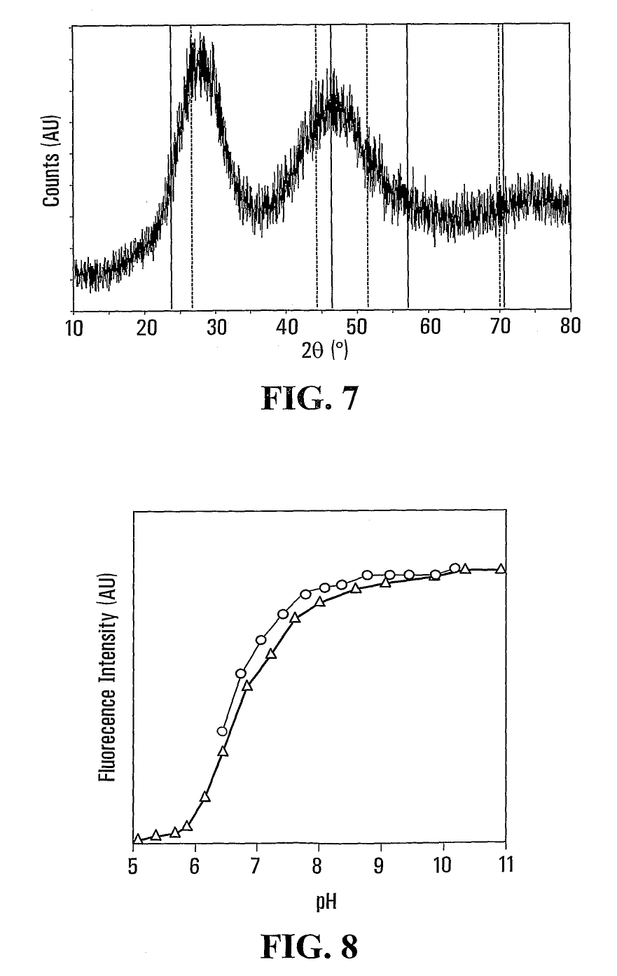

X-ray diffraction (XRD) pattern of vacuum-dried sample QD powder was obtained with a PANalytical X'Pert PRO™ Diffraction system. An example image is shown in FIG. 7. The sample QD powder exhibited an XRD peak at about 27° (002) and a broad band at about 47° due to overlap of (110), (103) and (112) diffractions. This confirms that the sample QDs have a zinc blende cubic crystal structure, like other thiol-capped CdTe QDs. For comparison, the XRD pattern for CdS quantum dots is also shown, which are marked as “CdS”.

The sample QDs were subjected to elemental analysis with an ELAN 9000/DRC™ Inductively Coupled Plasma Mass Spectrometer (ICP-MS). The analysis results show that the molar ratio of Cd:Te in the purified QDs is about 3.3:1, which is smaller than the molar ratio of 5:1 in the mixed solution.

It was calculated, based on the measured core size of about 4 nm and the zinc blende lattice structure, that the molar ratio of Cd:Te:GSH in a single sample QD is about 10:3:7.

It is also calculated, based on the grain size analysis, elemental analysis and absorption measurements, that the sample QDs with a fluorescence emission peak at 600 nm have a molecular weight of about 180,000 Dalton and a molar extinction coefficient at 470 nm of about 2×10⁵ M⁻¹cm⁻¹.

The sample QDs were further studies by ligand exchange with other thiol ligands. It has been found that the size and structure of the QDs were not affected by ligand exchange. However, the fluorescence quantum yield of the exchanged QDs was smaller than the sample QDs.

It has also been found that the sample QDs were stable in either pellet form or in an aqueous solution for several months when stored in air at about 4° C. in the dark. When the sample QDs are dispersed in a solution, their stability is dependent on the pH value of the solution. The fluorescence intensity of the sample QDs in solution depends on the pH value of the solution, as illustrated in FIG. 8. The round points are data points measured in a Tris-HCl buffer solution. The triangle points are data points measured in a phosphate buffer solution. As shown, the fluorescence intensity is roughly constant at pH above 9 and decreases at pH below 9. When pH value is below about 6, fluorescence is substantially quenched.

It has been found that the sample QDs did not aggregate after 3 days of incubation in various saline buffer solutions and cell culture media. Thus, these QDs are very stable and are suitable for cell labeling and bioimaging applications. Since the concentration of free GSH in many cells can be as high as 1-10 mM, the interference from other thiol ligands will be low and thus long-term in vivo stability of the sample QDs should be very good.

Studies of the sample QDs also showed that the sample QDs have very low toxicity or interference with cell viability or function, showing that the sample QDs can be suitable for live cell imaging.

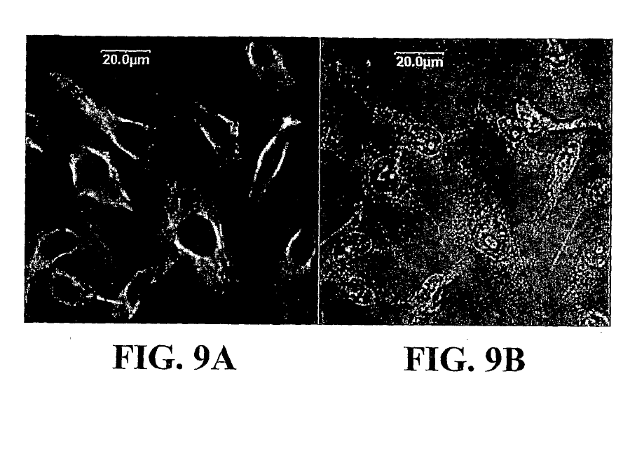

The sample QDs were also labeled with biotin, such as NHS-biotin. The biotin-labeled QDs were used to label actin on the skeleton of NIH3T3 cells through standard immunostaining procedures and were used successfully to image the NIH3T3 cells. For this study, the QD powders were re-dissolved in phosphate-buffered saline (PBS) buffer and incubated with N-hydroxysuccinimidobiotin (NHS- biotin) for two hours. Free NHS-biotin was removed by ultrafiltration. NIH3T3 cells were cultured on a cover slip, fixed with ice-cold methanol for 5-10 minutes, and blocked with 1% BSA in PBS buffer for one hour before immunostaining. Fixed cells on the cover slip were incubated in consecutive order with anti-actin monoclonal antibody, biotin-labeled goat anti-rabbit secondary antibody, streptavidin and biotin-labeled sample QDs. The cover slip was washed several times with PBS buffer after each incubation step. FIGS. 9A and 9B show two exemplary images of NIH3T3 cells which were actin immunostained with biotin-labeled QDs. The image in FIG. 9A is a confocal fluorescence image and the image in FIG. 9B is a transmission image. Fluorescence images were taken with an Olympus Fluoview 300™ confocal laser scanning system with 488-nm argon laser excitation. QD emission at 600 nm was detected with two chroma 570-nm longpass optical filters.

As discussed above, the QDs disclosed herein can have relatively small particle size and high quantum yield. The high quantum yield can be achieved without post-formation treatment. The QDs can also have high solubility in solutions of a wide range of pH. In addition, the QDs can exhibit high stability in cell culture.

Since each GSH molecule has one amino group and two carboxyl groups, GSH molecules can be cross-linked to each other. Thus, as can be understood by persons skilled in the art, the QDs disclosed herein can be bio-polymerized and stabilized with a matrix on a surface. They can also have high stability and low cytotoxicity.

The QDs disclosed herein can be used in various applications, such as for bio-labeling. The QDs can be used as bio-tags for in vitro or in vivo bioimaging, and as fluorescent probes for detection of DNA or proteins.

As can be understood, QDs can also be used in other fields such as in light-emitting devices, photonic and core-shell structures, optoelectronic and photovoltaic devices, optical amplifier media, and the like.

Other features, benefits and advantages of the embodiments described herein not expressly mentioned above can be understood from this description and the drawings by those skilled in the art.

The contents of each reference cited above are hereby incorporated herein by reference.

Of course, the above described embodiments are intended to be illustrative only and in no way limiting. The described embodiments are susceptible to many modifications of form, arrangement of parts, details and order of operation. The invention, rather, is intended to encompass all such modification within its scope, as defined by the claims.

1. A method of synthesizing quantum dots, comprising:
(a) providing a solution comprising a telluride (Te) precursor and a cadmium (Cd) precursor;
(b) growing, in said solution, nanocrystals comprising CdTe; and
(c) introducing glutathione (GSH) to said solution to form shells covering said nanocrystals, said nanocrystals and said shells forming quantum dots each having a core comprising CdTe and a shell comprising GSH.

2. The method of claim 1, wherein said telluride precursor is selected from sodium hydrotelluride (NaHTe) and hydrogen telluride (H₂Te).

3. The method of claim 1, wherein said cadmium precursor comprises a water-soluble Cd salt.

4. The method of claim 3 wherein said salt is selected from cadmium chloride (CdCl₂), cadmium perchloride, and cadmium acetate.

5. The method of claim 1, wherein said solution comprises water as a solvent.

6. The method of claim 1, wherein the molar ratio of Cd:Te in said solution is from about 3:1 to about 7:1, and the molar ratio of Te:GSH in said solution is from about 1:2 to about 1:10.

7. The method of claim 6, wherein the molar ratio of Cd:Te:GSH in said solution is about 5:1:5.

8. The method of claim 1, wherein said solution has a pH value from about 11.2 to about 11.8.

9. The method of claim 8, wherein said solution has a pH value of about 11.5.

10. The method of claim 1, wherein said growing comprises heating said solution to accelerate growth of said nanocrystals.

11. The method of claim 10, wherein said heating comprises heating said solution at a temperature of about 95° C.

12. The method of claim 10, wherein said solution is heated for a selected period of time.

13. The method of claim 12, further comprising cooling said solution after said solution has been heated for said selected period of time.

14. The method of claim 13, wherein said cooling comprises immersing said solution in an ice bath.

15. The method of claim 12, wherein said selected period of time is less than about 90 minutes.

16. The method of claim 12, wherein said selected period of time is selected to limit said growth of said nanocrystals, such that said quantum dots have core diameters from about 2.8 nm to about 5 nm.

17. The method of claim 16, wherein said core diameters have an average diameter of about 4 nm.

18. The method of claim 12, wherein said selected period of time is selected to limit said growth of said nanocrystals, such that said quantum dots have a selected fluorescence emission spectrum.

19. The method of claim 18, wherein said fluorescence emission spectrum peaks at a wavelength of about 500 to about 620 nm.

20. The method of claim 1, wherein said providing comprises preparing said solution by mixing a first precursor solution comprising said Te precursor and a second precursor solution comprising said Cd precursor, at least one of said first and second precursor solutions further comprising GSH.

21. The method of claim 1, wherein said providing comprises preparing said solution by bubbling a gas comprising hydrogen telluride (H₂Te) through a solution comprising said Cd precursor and said GSH.

22. A quantum dot comprising:
(d) a nanocrystal core comprising cadmium telluride (CdTe); and
(e) a shell covering said core, said shell comprising glutathione (GSH).

23. The quantum dot of claim 22, wherein said core has a diameter from about 2.8 nm to about 5 nm.

24. The quantum dot of claim 23, wherein said diameter is about 4 nm.

25. The quantum dot of claim 22, wherein said shell has a thickness of about 0.5 nm.

26. The quantum dot of claim 22, having a fluorescence quantum yield higher than about 16%.

27. The quantum dot of claim 26, wherein said quantum yield is from about 20% to about 25%.

28. The quantum dot of claim 26, wherein said quantum yield is from about 30% to about 45%.

29. The quantum dot of claim 22, having a fluorescence emission spectrum peaking at a wavelength of about 500 to about 620 nm.

30. The quantum dot of claim 22, wherein the molar ratio of Cd:Te in said core is from about 2.5:1 to about 3.5:1.

31. The quantum dot of claim 30, wherein the molar ratio of Cd:Te in said core is about 3.3:1.

32. The quantum dot of claim 22, wherein said shell has a thickness of about 0.5 nm.

33. A solution for forming quantum dots each comprising a CdTe core and a GSH shell, said solution comprising:
(f) a telluride (Te) precursor and a cadmium (Cd) precursor for forming CdTe cores, and
(g) glutathione (GSH) for forming shells covering said CdTe cores.

34. The solution of claim 33, wherein said telluride precursor is selected from sodium hydrotelluride (NaHTe) and hydrogen telluride (H₂Te).

35. The solution of claim 33, wherein said cadmium precursor comprises a water-soluble Cd salt.

36. The solution of claim 35, wherein said salt is selected from cadmium chloride (CdCl₂), cadmium perchloride, and cadmium acetate.

37. The solution of claim 33, having a pH value of from about 11.2 to about 11.8.

38. The solution of claim 37, having a pH value of about 11.5.

39. The solution of claim 33, wherein the molar ratio of Cd:Te is from about 3:1 to about 7:1, and the molar ratio of Te:GSH is from about 1:2 to about 1:10.

40. The solution of claim 33, wherein the molar ratio of Cd:Te:GSH is about 5:1:5.

41. A method of synthesizing quantum dots, comprising:
(h) forming quantum dots in a solution comprising a telluride (Te) precursor, a cadmium (Cd) precursor, and glutathione (GSH), such that each one of said quantum dots has a core comprising CdTe and a shell comprising GSH.
